(19) United States
(12) Patent Application Publication
(10) Pub. No.: US 2025/0076598 A1
(43) Pub. Date: Mar. 6, 2025

(54) PACKAGING STRUCTURE OF OPTOELECTRONIC ASSEMBLY, OPTOELECTRONIC ASSEMBLY USING SAME AND PREPARATION METHOD THEREOF

(71) Applicant: EverPro (Wuhan) Technologies Company Limited, Wuhan (CN)

(72) Inventors: Qunze Wang, Wuhan (CN); Yihuan Zhou, Beijing (CN); Hui Jiang, Beijing (CN); Xumao Wang, Wuhan (CN)

(21) Appl. No.: 18/633,440

(22) Filed: Apr. 11, 2024

(30) Foreign Application Priority Data
Aug. 29, 2023 (CN) 2023110982797

(51) Int. Cl. G02B 6/42; G02B 6/43

(52) U.S. Cl. CPC G02B 6/428; G02B 6/4214; G02B 6/423; G02B 6/43

(57) ABSTRACT

A packaging structure of optoelectronic assembly, optoelectronic assembly using same and preparation method thereof. The preparation method comprising, providing a PCB board with an electrical connection surface and an optical coupling surface at an interval; preparing the electrical connection surface and the optical coupling surface respectively; bonding electrical contacts; after mounting optical assembly and performing additional testing, cutting and preparing a plurality of PCB units, and preparing corresponding optoelectronic assembly. The invention can simultaneously prepare multiple optoelectronic assemblies, so assembly efficiency improved; burn-in test of a plurality of optoelectronic assemblies can be completed at one time, which reduces requirements for a testing tool, and can test a plurality of optoelectronic assemblies in batches with high testing efficiency; and the optoelectronic assembly is controlled to emit light through the testing tool, and the test method is simple; assembly process of the optoelectronic assembly is simple.

### CROSS-REFERENCE TO RELEVANT APPLICATIONS

The present application claims the priority of Chinese Patent Application 2023110982797 filed on Aug. 29, 2023, the entire contents of which is hereby incorporated by reference.

### TECHNICAL FIELD

The present invention relates to the field of optical communications, and particularly, relates to a packaging structure of an optoelectronic assembly, an optoelectronic assembly using same and a preparation method thereof, which improve preparation efficiency of the optoelectronic assembly and simplify an assembly process and a burn-in test method.

### BACKGROUND

With the improvement of the density and integration of communication electronic equipment, an optical transceiver module needs to be packaged with smaller size.

A common way in the industry is to package a chip in a Sub-PCBA, which is connected with an optical fiber connector, and then assembled to a main PCB together. A Sub-PCBA has certain universality. This structure omits a lens for optical path conversion, but limits optical alignment between the Sub-PCBA and the optical fiber connector to active alignment only, which takes longer alignment time than passive alignment and is inefficient in production. Moreover, a main PCBA and the Sub-PCBA of this structure are fixed at 90 degrees. A circuit pad between the main PCBA and the Sub-PCBA may also be welded at a 90-degree angle. It is difficult to apply this structure to a widely used reflow soldering surface mount technology at present, and the production efficiency is low.

Alternatively, an optical transceiver is welded on a printed circuit board and then assembled to a base together. This optical transceiver module can greatly reduce a packaging area of the module and meanwhile, improve using reliability and replaceability of the module. However, in the optical transceiver module, the optical transceiver and the printed circuit board are mounted in the base, and the optical transceiver needs a fixed position provided by the base, otherwise the optical transceiver cannot be coupled and aligned with an optical fiber. This structure has many parts and is complicated to assemble.

However, the production of an improved optoelectronic assembly at present is usually realized on a single substrate, and a single module is chip mounted and optically coupled, and then subjected to a burn-in test. This method has high requirements for clamping fixture and low production efficiency, and the burn-in test can be realized by a special burn-in box. This method is not beneficial for cost reduction.

Therefore, how to overcome the defects of the prior art, simplify the structure and process of the optoelectronic assembly, and apply the optoelectronic assembly to the reflow soldering surface mount technology become technical problems that need to be solved urgently in the prior art. Moreover, how to improve the structure of the optoelectronic assembly, simplify the preparation method of the optoelectronic assembly and reduce the production cost are also technical problems that need to be solved urgently.

### SUMMARY

The present invention aims to provide a packaging structure of a optoelectronic assembly, a optoelectronic assembly using same and a preparation method thereof, which can use a reflow soldering surface mount technology, simplify an assembly process, reduce a production cost, tolerate a high temperature and a high pressure of injection molding and is suitable for an injection molding process. The present invention also aims to provide a optoelectronic assembly and a preparation method thereof, which can improve an assembly efficiency, simplify a burn-in test method, improve a test efficiency, simplify a burn-in test box and save an equipment cost.

In order to achieve this object, the present invention adopts the following technical solutions.

A packaging structure of a optoelectronic assembly includes a substrate with central symmetry, wherein one side of the substrate is provided with a plurality of optical transceivers and driver chips, and the other side of the substrate is provided with a plurality of electrical contacts;
the optical transceivers, the driver chips and the electrical contacts form data channels, and the data channels are used for receiving or transmitting data;
the electrical contacts include a plurality of first contacts and a plurality of second contacts, solder is arranged on the first contacts, and a surface tension generated when the solder melts keeps the first contacts in an original position;
the second contacts are each arranged on a periphery of the first contacts, solder is arranged on the second contacts, and a surface tension generated when the solder melts keeps the second contacts in an original position;
a space is arranged between the first contacts and the second contacts, so that the first contacts and the second contacts are insulated from each other after the solder on the first contacts melts; and
a surface area of the first contact is greater than a surface area of the second contact.

Alternatively, each of the first contacts is symmetrically arranged relative to a center of the substrate, and each of the second contacts is symmetrically arranged relative to the center of the substrate.

Alternatively, the second contacts are arranged in four rows, symmetrically arranged on the substrate, and the second contacts in two adjacent rows are staggered.

Alternatively, the surface area of the first contact is at least twice the surface area of the second contact.

Alternatively, the second contacts include power supply terminals, ground terminals and signal terminals, and the power supply terminal, the ground terminal and the signal terminal are staggered.

Alternatively, the second contacts are arranged in four rows, and symmetrically arranged on four peripheries of the substrate.

The present invention further discloses an optoelectronic assembly used for being coupled with an optical fiber, and the packaging structure of the optoelectronic assembly above further includes an optical assembly, wherein the optical transceiver is coupled with the optical fiber through the optical assembly.

Alternatively, the optical assembly includes a first lens, a second lens and a reflection plane, the optical assembly is provided with one accommodating cavity, the first lens is aligned with an emission window of the optical transceiver and the optical assembly is attached to the substrate, and the second lens is aligned with an end face of the optical fiber.

Alternatively, a first protective cover is further included, the first protective cover is covered outside the first lens, the second lens and the reflection plane.

Alternatively, the optical assembly is an optical fiber guide hole, the optical transceiver is mounted on a bracket, and the bracket is mounted on the substrate to convert an optical path of the optical transceiver.

Alternatively, a second protective cover is further included, and the second protective cover is covered outside the driver chip and the bracket.

The present invention further discloses a photoelectric unit, including the optoelectronic assembly above; and a semi-circular through hole that are located on the side edge of the optoelectronic assembly, are connected with a bottom board.

Alternatively, when a driver chip and the optical transceiver are mounted on an optical coupling surface, and the optical transceiver is coupled with an optical fiber through a optical assembly.

Alternatively, the optical assembly includes a first lens, a second lens and a reflection plane, the optical assembly is provided with one accommodating cavity, the first lens is coupled with an emission window of the optical transceiver, and the second lens is coupled with an end face of the optical fiber.

Alternatively, the optoelectronic assembly further comprising, a first protective cover, wherein the first protective cover is provided on the outside of the first lens, the second lens and the reflection plane.

Alternatively, when the optical transceiver is mounted on the optical coupling surface through a bracket, the optical assembly is an optical fiber guide hole, and

a side frame is further provided on the optical coupling surface, and the optical fiber guide hole is mounted on the side frame, and the optical fiber guide hole is aligned with a center of the emission window of the optical transceiver.

Alternatively, a second protective cover is further included, and the second protective cover is provided on the outside of the driver chips and the bracket.

A preparation method of a optoelectronic assembly, includes the following steps of:
carrier preparation step S110, including,
acquiring a prepared PCB board, wherein the PCB board is provided with an electrical connection surface and an optical coupling surface at an interval, the PCB board is provided with a plurality of PCB units, and each PCB unit corresponds to an optoelectronic assembly to be prepared;
electrical connection surface preparation step S120, including,
printing and preparing metal pads on the electrical connection surface, wherein each of the metal pads includes a plurality of first contacts at a central position and a plurality of second contacts at a periphery of the first contacts, and a surface area of the first contact is larger than a surface area of the second contact; and fixing solder on the first contacts and the second contact;
chip attaching step S130, including,
attaching a plurality of driver chips and a plurality of optical transceivers on the optical coupling surface; and
bonding step S140, including,
electrically connecting electrical contacts of the plurality of driver chips, electrical contacts of the plurality of optical transceivers and electrical contacts of the PCB board with each other.

Alternatively, the method further includes:
optical assembly mounting step S150, including,
aligning and fixing the optical assemblies with the optical transceivers; and
PCB unit preparation step S160, including,
cutting the PCB board into a plurality of PCB units by using precision cutting, wherein a side edge of the PCB unit is provided with a plurality of semi-circular through holes.

Alternatively, in the electrical connection surface preparation step S120, the electrical connection surface is prepared by using a printing plate, the printing plate is provided with a plurality of first through holes and a plurality of second through holes, wherein the first through holes correspond to the first contacts and the second through holes correspond to the second contacts, and the electrical connection surface is prepared by applying solder paste.

Alternatively, the first through hole is aligned with a center of the first contact, the second through hole is aligned with a center of the second contact, and a first size of the first through hole of the printing plate is 40%-60% of a second size of the first contact; and a third size of the second through hole is 40%-60% of a forth size of the second contact.

Alternatively, in the electrical connection surface preparation step S120, the fixing solder on the first contacts and the second contacts specifically includes:
distributing and attaching prefabricated solder balls to positions on the printing plate with the solder paste, melting the solder paste and fixing the solder balls by hot-blast heating, and then taking the printing plate away, wherein a temperature of the hot-blast heating is higher than a melting point of the solder paste and lower than a melting point of the solder ball.

Alternatively, in the electrical connection surface preparation step S120, the fixing solder on the first contacts and the second contacts specifically includes:
taking the printing plate away and heating the solder paste to fix the solder paste on the PCB board.

Alternatively, in the chip attaching step S130,
the driver chips are mounted on the optical coupling surface, the optical transceivers are mounted on brackets respectively, and each of the the brackets is vertically mounted on the optical coupling surface; or
the driver chips and the optical transceivers are mounted on the optical coupling surface.

Alternatively, between the bonding step S140 and the optical assembly mounting step S150, there is also a burn-in test step S145, wherein the burn-in test step S145 includes,
arranging the PCB board on a burn-in carrying tool, setting burn-in conditions, and performing a burn-in test on the optoelectronic assembly.

Alternatively, the burn-in carrying tool includes a body, a cover board, and a test bottom board, the PCB board is placed in a groove of the body and fixed by the cover board, the test bottom board is arranged at a lower part of the body and provided with probes; and the probes pass through the body, maintaining a relative position between the test bottom board body to electrically connect with test contacts respectively.

Alternatively, the test bottom board controls each of the optical transceivers of each of the plurality of PCB units to emit light in sequence;
when the optical transceivers of each of the plurality of PCB units emit light, a light detecting unit is moved to a position of corresponding optical transceiver to detect a light intensity; and
according to light intensity changes of the optical transceivers of each PCB unit before and after the burn-in test, qualified PCB units are selected.

The present invention further discloses an optoelectronic assembly prepared by using the above method.

The present invention has the following advantages.

1. According to the packaging structure of the optoelectronic assembly, the optical transceiver is directly mounted on the base, a pedestal is not needed, only the optical transceiver and the printed circuit board are provided, so the assembly process is simple.

2. The back of the PCB unit is provided with the plurality of electrical contacts, which are used for connecting signals, power supply and ground, and can be connected with the bottom board through SMT welding, and are suitable for reflow soldering surface mount technology.

3. The accommodating space is formed by the protective cover and the PCB unit. The protective cover is made of metal or ceramic, and the optical assembly is made by an integral molding process, with no gap on the surface thereof. The protective cover and the PCB unit are sealed by high-temperature resistant glue, so that the whole module is integrated, which can prevent injection molding materials from entering the cavity and avoid the damage of the optical transceiver and the driver during injection molding.

4. The accommodating space is formed by the protective cover and the PCB unit, and the optical path coupling between the optical transceiver and the optical fiber is realized by different ways such as the optical assembly or the optical fiber guide hole, so that the structure is flexible and simple.

5. A small optoelectronic assembly can be formed, and the burn-in test of the light emitting device can be realized in a connecting plate stage. Undesirable devices can be found earlier, so the cost is saved. At the same time, the efficiency of the burn-in test is improved. A burn-in test interface can be realized by means of gold finger, board to board connector or probes.

6. A large carrier is provided with the plurality of PCB units, and the plurality of PCB units are cut after the preparation process is completed, so as to prepare the corresponding optoelectronic assemblies and improve the assembly efficiency.

7. The burn-in test is carried out before cutting, so that the burn-in test of a plurality of optoelectronic assemblies can be completed at one time, which reduces requirements for a testing tool, and can test a plurality of optoelectronic assemblies in batches with high testing efficiency; and each of the optoelectronic assemblies is controlled to emit light through the testing tool, and the test method is simple.

### BRIEF DESCRIPTION OF THE DRAWINGS

FIG. 1 is a schematic diagram showing one side of a PCB unit in a packaging structure of an optoelectronic assembly in some embodiments of the present invention;

FIG. 2 is a schematic diagram showing the other side of the PCB unit in the packaging structure of the optoelectronic assembly in some embodiments of the present invention;

FIG. 3 is a schematic diagram of a PCB unit in a packaging structure of an optoelectronic assembly in some embodiments of the present invention;

FIG. 4 is an operational schematic diagram of an optical assembly in some embodiments of the present invention;

FIG. 5 is an assembly schematic diagram of the optical assembly in some embodiments of the present invention;

FIG. 6 is a schematic diagram of an optical assembly in some embodiments of the present invention;

FIG. 7 is a plan view of the optical assembly in some embodiments of the present invention;

FIG. 8 is a flow chart of a preparation method of an optoelectronic assembly in some embodiments of the present invention;

FIG. 9 is a view when devices are not attached to an optical coupling surface of a PCB board in the preparation method of the present invention;

FIG. 10 is a view when devices are attached to the optical coupling surface of the PCB board in the preparation method of the present invention;

FIG. 11 is a schematic diagram of an electric connection unit of the optoelectronic assembly in some embodiments of the present invention; and

FIG. 12 is a view of putting a PCB board according to the preparation method of the present invention into a burn-in carrying tool for a burn-in test;

Reference numerals in the figure respectively refer to the following technical features:
1 refers to substrate; 2 refers to first protective cover; 3 refers to optical assembly; 4 refers to bracket; 5 refers to side frame; 6 refers to optical fiber guide hole; 7 refers to optical fiber; 8 refers to second protective cover; 11 refers to first contact; 12 refers to second contact; 21 refers to electric connection unit; 22 refers to optical coupling unit; 31 refers to driver chip; 32 refers to optical transceiver; 33 refers to first lens; 34 refers to reflector; 35 refers to second lens; 41 refers to body; 42 refers to cover board; 43 refers to test bottom board; and 44 refers to probes.

### DETAILED DESCRIPTION OF THE EMBODIMENTS

The present invention will be further described in detail below with reference to the drawings and embodiments. It may be understood that the specific embodiments described herein are merely illustrative of the present invention and are not intended to limit the present invention. In addition, it should also be noted that, for case of description, the drawings show only a portion of the contents related to the present invention, but not all the structures.

The present invention mainly lies in that: a substrate is directly adopted to form a packaging structure of an optoelectronic assembly without a base, one side of the substrate is provided with a plurality of optical transceivers and driver chips, and the other side is provided with a plurality of electrical contacts for connecting signals, power supply and ground, and can be connected with a bottom board through SMT welding, and first contacts and second contacts have different surface areas. Specifically, the surface area of the first contact is greater than the surface area of the second contact, a space is provided between the first contacts and the second contacts, so that the first contacts and the second contacts are kept in original positions by surface tension, and the contacts are insulated. Therefore, the present invention is not only suitable for a reflow soldering surface mount technology, but also simplifies an assembly process.

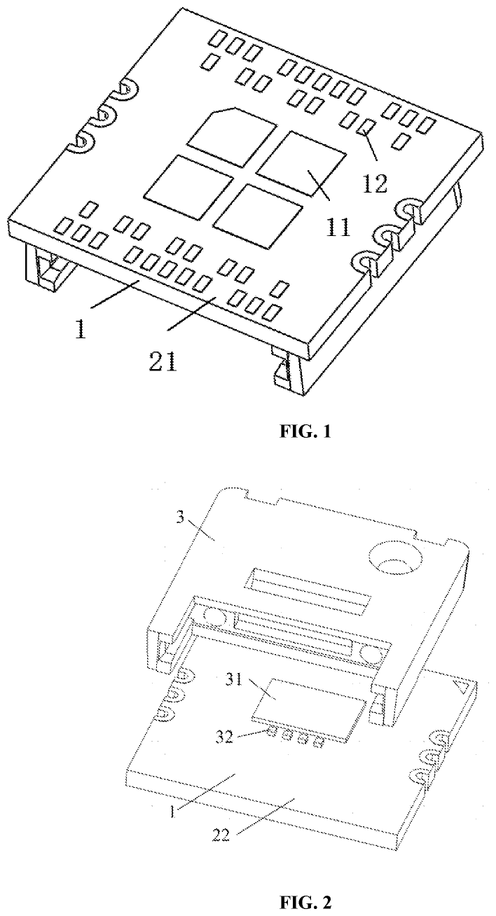

Specifically, refer to FIG. 1 and FIG. 2, which show schematic diagrams of two surfaces of a packaging structure of a small optoelectronic assembly in some embodiments of the present invention.

A substrate 1 with central symmetry is included, wherein one side of the substrate is provided with a plurality of optical transceivers 32 and driver chips 31, and the other side of the substrate is provided with a plurality of electrical contacts.

The optical transceivers 32, the driver chips 31 and the electrical contacts form data channels, and the data channels are used for receiving or transmitting data.

The electrical contacts include a plurality of first contacts 11 and a plurality of second contacts 12, solder is arranged on the first contacts 11, and a surface tension generated when the solder melts keeps the first contacts in an original position.

The second contacts 12 are each arranged on a periphery of the first contacts, solder is arranged on the second contacts, and a surface tension generated when the solder melts keeps the second contacts in an original position.

A space is arranged between the first contacts 11 and the second contacts 12, so that the first contacts 11 and the second contacts 12 are insulated from each other after the solder on the first contacts 11 melts.

A surface area of the first contact 11 is greater than a surface area of the second contact 12.

In an exemplary embodiment, the substrate 1 may be a printed circuit board.

Therefore, the present invention does not need a base, simplifies the assembly process, and only the optical transceivers and the printed circuit board form the small optoelectronic assembly.

Further, the substrate may be connected with the bottom board through the SMT welding technology, which is suitable for the reflow soldering surface mount technology.

Each of the first contacts 11 is symmetrically arranged relative to a center of the substrate 1, for example, arranged in an array, and each of the second contacts 12 is symmetrically arranged relative to the center of the substrate 1.

The surface area of the first contact 11 is greater than the surface area of the second contact 12. A large pad in the middle has a large area, and tin on the large pad can provide a large surface tension after melting, which ensures that the module may not deviate when the tin melts during SMT welding, and the surface tension may pull the module back to a position of the large pad. The second contacts 12 located around the substrate are arranged on the periphery of the first contacts 11. Preferably, the second contacts 12 are symmetrically arranged relative to the center of the substrate 1, and the surface tensions of the molten tin on the pads of the second contacts are equal up and down, left and right, but opposite in directions, which can just balance out.

The first contacts 11 are connected to a same electrical network to avoid short circuit therebetween, and the first contacts 11 and the second contacts 12 are separated, so that the first contacts and the second contacts are insulated from each other to avoid short circuit after the solder on the first contacts melts.

In a specific embodiment, referring to FIG. 1, the second contacts 12 are arranged in four rows, symmetrically arranged on the substrate 1, and the second contacts 12 in two adjacent rows are staggered.

The second contacts 12 include power supply terminals, ground terminals and signal terminals, and the power supply terminal, the ground terminal and the signal terminal are staggered, so that power supply integrity of high-speed signals can be ensured. Meanwhile, the signal terminals are staggered in two rows, which is convenient for signal fan-out in the inner row and reduces complexity of the bottom board butted with the module.

Each of optical transceiver 32 on a front of the substrate 1 is connected with a channel corresponding to one driver chip 31, and the channel is then connected to the electrical contact at a back of the substrate 1. The optical transceiver 32, the channel of the driver chip 31 and the electrical contact form one transmitting/receiving data channel which is used for receiving or transmitting data. Free combination of a plurality of the transmitting/receiving channels may be used to transmit different data protocols, such as USB3.0, Display Port, HDMI, DVI, PCIE and the like.

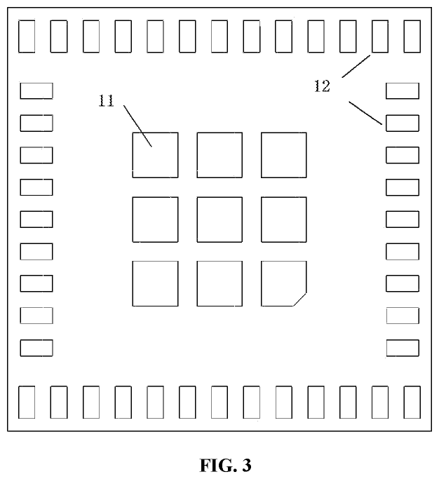

In another specific embodiment, referring to FIG. 3, the second contacts 12 are arranged in four rows, symmetrically arranged on a periphery of the substrate 1.

In a further preferred embodiment of the present invention, a surface area of the first contact 11 is at least twice a surface area of the second contact 12.

The first contacts 11 may be ground terminals.

The present invention further discloses an optoelectronic assembly used for being coupled with an optical fiber, the optoelectronic assembly includes the packaging structure of the optoelectronic assembly above, and further includes an optical assembly 3, wherein the optical transceiver 32 is coupled with the optical fiber 9 through the optical assembly 3.

### Embodiment 1

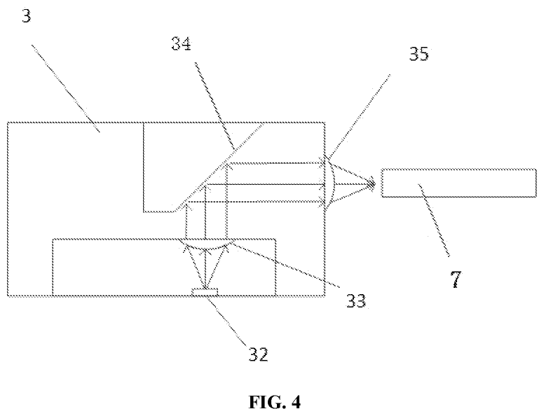

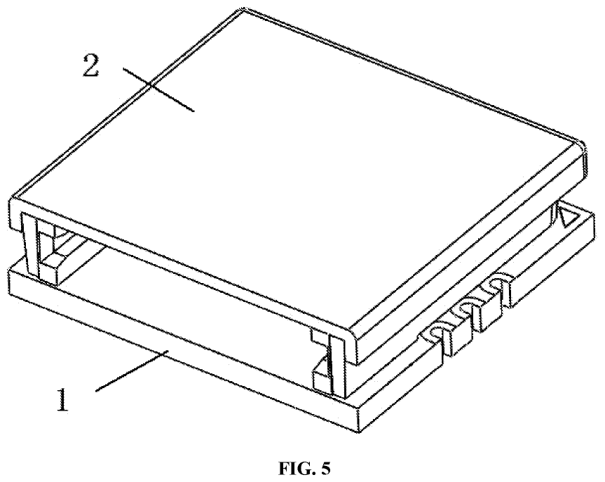

Refer to FIG. 4 and FIG. 5, which show an optical assembly in some embodiments of the present invention.

In those embodiments, an optical assembly 3 includes a first lens 33, a second lens 35 and a reflection plane 34. The optical module 3 is provided with an accommodating cavity. The first lens is aligned with an emission window of an optical transceiver 32, and the optical assembly 3 is attached to a substrate. The reflection plane 34 is used for coupling an optical path of the first lens 33 with an optical path of the second lens 35, and the second lens 35 is aligned with an end face of an optical fiber 7.

In one embodiment, the first lens 33 may be a horizontally arranged lens, an emitting surface of the reflection plane 34 may form an included angle of 45 degrees with a horizontal plane, and the second lens 35 may be a vertically arranged lens. The horizontally arranged lens is used to align the emission window of the optical transceiver 32 and attached to the substrate 1, and the reflection plane 34 couples an optical path in a vertical direction with an optical path in a horizontal direction.

In another embodiment, the first lens 33 may be a divergent lens for changing lights emitted by a Vertical-Cavity Surface-Emitting Laser (VCSEL) into a group of parallel lights. The reflection plane 34 is a reflection plane with an oblique angle of 45 degrees for changing a propagation direction of a received light beam. The second lens 35 may be a convergent lens, which converges the reflected light beam on the optical fiber 7. The first lens 33 is used to align the emission window of the optical transceiver 32, and the reflection plane 34 emits the received light beam in a vertical incident direction, thereby changing an optical path direction.

The optoelectronic assembly further includes a first protective cover 2, and the first protective cover 2 is provided on the outside of the first lens 33, the second lens 35 and the reflection plane 34.

The optical assembly is made of a plastic-like material, which cannot withstand the temperature of SMT, so the protective cover made of a ceramic material is installed on the optical assembly. A side surface of the protective cover 2 can protrude downwards, thus providing thermal insulation protection for a top surface and a side surface of the optical assembly 3, and a lower side of the optical assembly 3 is the substrate. When the optical transceiver 32 and the driver chip 31 are located in a cavity of the optical assembly, this can provide all-round protection for the optical assembly and other components, so that the optical assembly may not be damaged due to overheating during SMT.

The optical assembly is made by an integrated molding process, and a surface thereof has no gap, which can resist injection molding materials into the cavity and avoid the damage of the optical transceiver and the driver during injection molding. Because the cavity accommodates the optical receiver and the driver, an upper wall of the optical assembly 3 at the position where the cavity is located will be insufficient in intensity as the upper wall is thin. During injection molding, a pressure of injection molding may make the upper wall bend downwards and touch gold threads used to connect the driver and the optical transceiver as well as between the driver and the optical transceiver and a bottom board, thus causing short circuit of the gold threads and eventually leading to the failure of the module. The protective cover can reinforce the upper wall of the optical assembly, reduce a deformation amount of a top cover of the optical assembly during injection molding, and the optical assembly may not be damaged by touching the gold threads due to pressurized deformation during injection molding.

### Embodiment 2

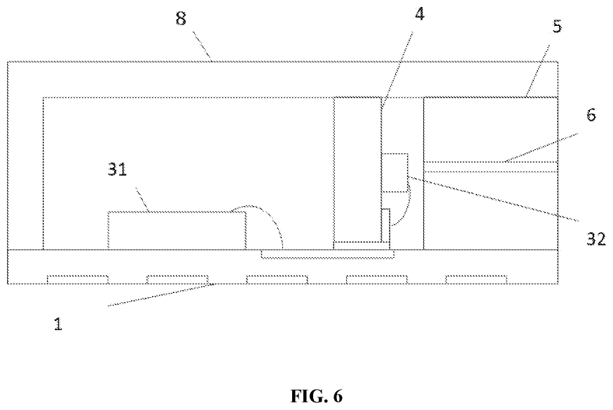

Refer to FIG. 6, which shows some embodiments of the optical assembly according to the present invention. Optical path coupling between the optical transceiver and the optical fiber may also be achieved by an optical fiber guide hole.

The optical assembly is an optical fiber guide hole 6, the optical transceiver 32 is mounted on a bracket 4, and the bracket 4 is mounted on the substrate 1. The optical fiber guide hole 6 is aligned with a center of the emission window of the optical transceiver 32, thus realizing the optical path coupling between the optical fiber and the optical transceiver.

In this embodiment, a front surface and a side surface of the bracket 4 may be provided with conductive lines. After the bracket 4 is rotated by 90 degrees, the bracket is mounted on the substrate 1. The optical fiber guide hole 6 is mounted on a side frame 5, and the optical fiber guide hole 6 is aligned with the center of the emission window of the optical transceiver 32. Therefore, when the optical fiber is inserted into the optical fiber guide hole, the optical coupling between the optical fiber and the optical transceiver can be realized.

Further, a second protective cover 8 is further included. The second protective cover 8 is provided on the outside of the driver chips and the bracket.

The second protective cover 8 and the substrate 1 may be sealed with a high-temperature resistant glue, so that the whole optoelectronic assembly can be integrated. The injection molding materials can be prevented from into the cavity, avoid the damage of the optical transceiver and the driver during injection molding, and the deformation of the whole optoelectronic assembly may not damage the devices in the cavity of the optical assembly 3 under injection pressure.

### Embodiment 3

The present invention further discloses a preparation method of an optoelectronic assembly.

On a large carrier, such as a large single PCB board, an electrical connection surface and an optical coupling surface are arranged at an interval along a thickness direction, a plurality of electrical connection units are arranged on the electrical connection surface, and a plurality of optical coupling units are arranged on the optical coupling surface. After preparing the electrical connection surface, the optical coupling surface and an additional testing step, a plurality of PCB units are cut and prepared (corresponding to the substrate 1 of the embodiment provided above), thereby preparing the corresponding optoelectronic assemblies, improving an assembly efficiency, simplifying a burn-in test method, improving a testing efficiency, simplifying a burn-in test box and saving an equipment cost.

In the following embodiments, a PCB board is taken as an example of a carrier, but the present invention is not limited to this, and the carrier may also be a ceramic carrier, both of which are within the scope of the present invention.

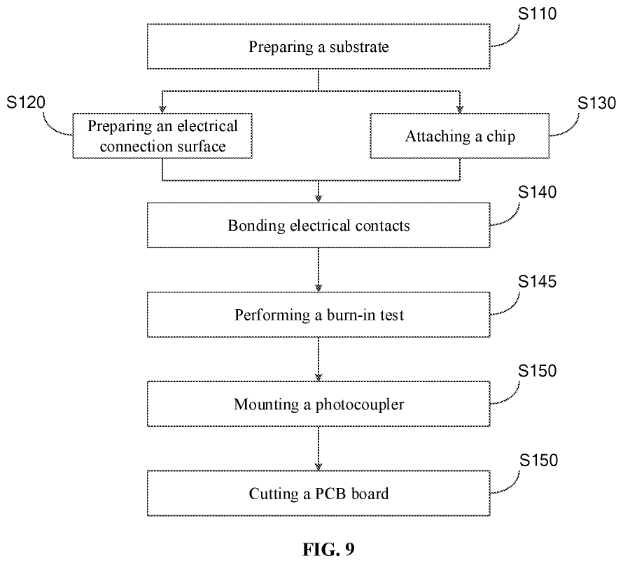

Refer to FIG. 9, which shows a flow chart of the preparation method of the optoelectronic assembly according to the present invention. The method includes the following steps.

Carrier preparation step S110, including,
acquiring a prepared PCB board, wherein the PCB board is provided with an electrical connection surface and an optical coupling surface at an interval, the PCB board is provided with a plurality of PCB units, and each PCB unit corresponds to an optoelectronic assembly to be prepared, that is, the PCB board provided with the plurality of PCB units of the present invention can form a plurality of optoelectronic assemblies at the same time.

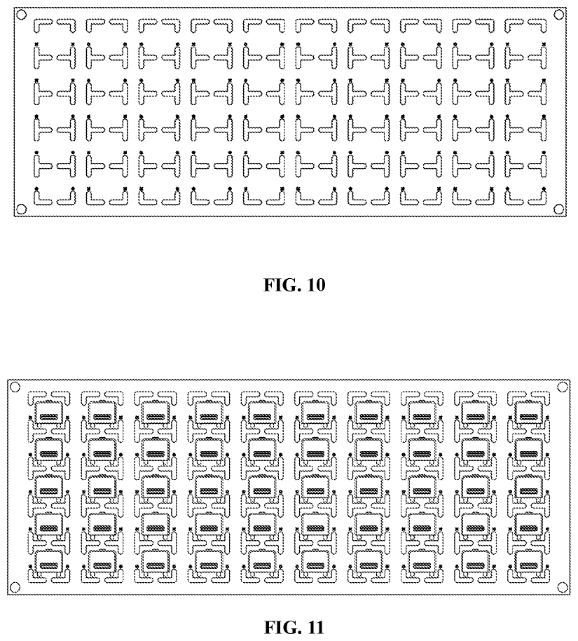

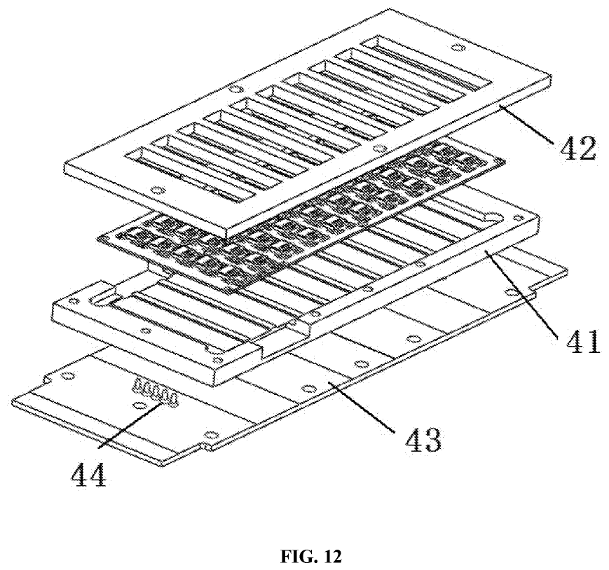

Refer to FIG. 10 and FIG. 11, which respectively show when devices are not attached and devices are attached to the optical coupling surface of the PCB board in the preparation method of the present invention.

The electrical connection surface is provided with a plurality of electric connection units, and the optical coupling surface is provided with a plurality of optical coupling units. Specifically, FIG. 1 and FIG. 2 show a prepared single photovoltaic module, wherein FIG. 1 shows an electrical connection unit 21 and FIG. 2 shows an optical coupling unit 22. The electrical connection unit 21 and the optical coupling unit 22 respectively correspond to one of the two surfaces of the PCB unit.

Electrical connection surface preparation step S120, including,
printing and preparing metal pads on the electrical connection surface, wherein each of the metal pads comprises a plurality of first contacts 11 at a central position and a plurality of second contacts 12 at a periphery of the first contacts, and a surface area of the first contact 11 is larger than a surface area of the second contact 12; and fixing solder on the first contacts 11 and the second contacts 12.

Chip attaching step S130, including,
attaching a plurality of driver chips 31 and a plurality of optical transceivers 32 on the optical coupling surface 22. This step is used for preparing the optical coupling surface.

In one alternative embodiment, other electrical devices, such as capacitors and Electro Magnetic Interference (EMI) devices, are attached to the optical coupling surface. Solder paste can be printed on the optical coupling surface corresponding to the attaching position, and then the electrical devices to be attached are mounted to target positions, and then the electrical devices are fixed to the target positions by means of reflow soldering or wave soldering. After the above-mentioned electrical devices are fixedly mounted, the drivers and the optical transceivers are attached to the target positions.

Therefore, according to the optoelectronic assembly prepared by the present invention, a pedestal is not needed, the PCB units are directly used to form the packaging structure of the optoelectronic assembly. One side of the PCB unit is provided with the plurality of optical transceivers and driver chips, and the other side of the PCB unit is provided with a plurality of electrical contacts for connecting signals, power supply and ground, which can be connected with the bottom board through Surface Mount Technology (SMT). The first contacts and the second contacts have different surface areas. Specifically, the first contact is larger than the second contact and is provided with a gap. The first contacts and the second contacts are kept in the original positions and insulated from each other by surface tension. Therefore, the present invention is not only suitable for a reflow soldering surface mount technology, but also simplifies an assembly process.

Step S120 and step S130 are used to prepare the electrical connection surface and the optical coupling surface respectively. The present invention does not limit the execution sequence of the step S120 and the step S130, and only needs to complete the preparation of the corresponding surfaces of the PCB board by using related steps. For example, after one of the step S120 and the step S130 is performed to complete the preparation of the corresponding one of the electrical connection surface and the optical coupling surface, the PCB board is turned over by 180 degrees, and the other one of the steps S120 and the S130 is used to complete the preparation of the other one of the electrical connection surface and the optical coupling surface.

Bonding step S140, including,
electrically connecting electrical contacts of the plurality of driver chips, electrical contacts of the plurality of optical transceivers and electrical contacts of the PCB board with each other.

In a specific embodiment, the electrical contacts of the driver chips 31 and the electrical contacts of the optical transceivers 32 can be electrically connected by wire connection, but the present invention is not limited to this, and any electrical connection mode is within the protection scope of the present invention. As can be seen from the above description, the bonding step S140 is preferably performed after the step S120 and the step S130, thereby increasing a product stability. For example, when preparing the electrical connection surface after bonding, it is easy to damage a connection stability of the electrical wires, thus damaging a product quality.

Optical assembly mounting step S150, including, aligning and fixing the optical assemblies with the optical transceivers.

This step mainly lies in aligning a center of the optical channel on each of the optical assemblies with a center of the emission window of each of the optical transceivers.

PCB unit preparation step S160, including,
cutting the PCB board into a plurality of PCB units by using precision cutting, wherein a side edge of the PCB unit is provided with a plurality of semi-circular through holes.

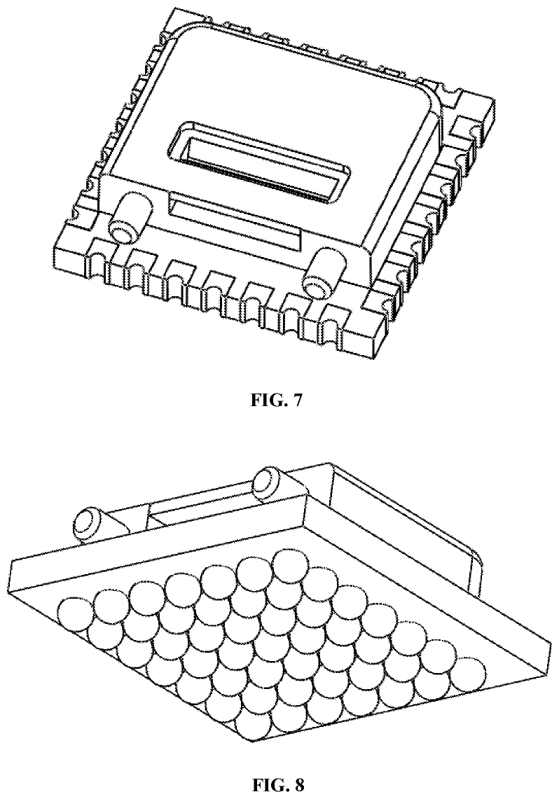

This step is used to form a single optoelectronic assembly. Refer to FIG. 7, which shows a schematic diagram of the optoelectronic assembly corresponding to the cut PCB unit in the preparation method according to the present invention.

Metallized semi-circular through holes are arranged around the optoelectronic assembly, and the metallized semi-circular through holes are connected with the bottom board. The metallized semi-circular through hole can not only have a positioning function to realize alignment with the bottom board, but also have an electrical connection channel, which can increase the electrical connection between the optical coupling surface and the bottom board.

By the method of the present invention, a large PCB board can be prepared and cut into a plurality of PCB units, thereby preparing the corresponding optoelectronic assemblies and improving the assembly efficiency.

Referring to FIG. 8, a metal pad is arranged on the electrical connection surface of the optoelectronic assembly, and spherical solder balls are mounted on the metal pad.

In the electrical connection surface preparation step S120, the metal pads of the electrical connection surface may be prepared by using a printing plate.

The printing plate is provided with a plurality of first through holes and a plurality of second through holes, the first through holes correspond to the first contacts, the second through holes correspond to the second contacts, and solder paste is coated to prepare the electrical connection surface.

A thickness of the printing plate is less than or equal 0.1 mm. When the printing plate is attached to an upper surface of the electrical connection surface, a flatness of the printing plate is consistent with that of the electrical connection surface.

The first through hole is aligned with a center of the first contact, the second through hole is aligned with a center of the second contact, and a first size of the first through hole of the printing plate is 40%-60% of a second size of the first contact; and a third size of the second through hole is 40%-60% of a fourth size of the second contact.

The solder includes solder balls and solder paste, and the metal pads may be provided with both the solder balls and the solder paste, and may also be provided with the solder paste only.

When the metal pads are provided with the solder balls and the solder paste, in the electrical connection surface preparation step S120, the fixing the solder on the first contacts and the second contacts specifically includes:

distributing and attaching prefabricated solder balls to positions on the printing plate with the solder paste, melting the solder paste and fixing the solder balls by hot-blast heating, and then taking the printing plate away, wherein a temperature of the hot-blast heating is higher than a melting point of the solder paste and lower than a melting point of the solder ball.

Melting the solder paste and fixing the solder balls by hot-blast heating can not only blow away the redundant solder balls, but also simply the process, and is simple and convenient to operate.

The solder ball can increase a welding intensity, especially when a density of solder joints on the bottom board is high, which is beneficial to the alignment of the optoelectronic assembly and the solder joints on the bottom board.

When the metal pads are provided with no solder balls, but only the solder paste, in the electrical connection surface preparation step S120, the fixing the solder on the first contacts and the second contacts specifically includes:

taking the printing plate away and heating the solder paste to fix the solder paste on the PCB board.

When the printing is finished, whether the solder paste meets the design requirements is detected, if not, the solder paste is erased, and the electrical connection surface preparation step S120 is performed again.

In the chip attaching step S130, the drivers and the optical transceivers can be located at different positions, and can be mounted at designed positions according to the design requirements.

For example, referring to FIG. 2, the driver chip 31 and the optical transceiver 32 are mounted on the optical coupling unit 22.

Alternatively, referring to FIG. 6, the driver chip 31 is mounted on the optical coupling unit 22, the optical transceiver 32 is mounted on the bracket 4, and the bracket 4 is vertically mounted on the optical coupling unit 22.

In this step, photosensitive surfaces of the plurality of optical transceivers corresponding to the optical coupling unit are consistent in height.

The optical transceiver may be disabled or fail in advance during use. In the process of production and preparation, it is necessary to carry out a burn-in test on the optoelectronic assemblies to ensure a stability and a reliability of the chips.

Therefore, further, between the bonding step S140 and the optical assembly mounting step S150, there is also a burn-in test step S145, wherein the burn-in test step S145 including, arranging the PCB board on a burn-in carrying tool, setting burn-in conditions, and performing a burn-in test on the optoelectronic assemblies. The burn-in conditions include a driving current, an ambient temperature and a burn-in time. During the burn-in process, the optoelectronic assemblies emit light at the same time, so the test environment is relatively simple, and the burn-in of a plurality of optoelectronic assemblies can be completed at one time, with high burn-in efficiency, and requirements for burn-in tools are reduced.

Referring to FIG. 12, the burn-in carrying tool includes a body 41, a cover board 42 and a test bottom board 43. The PCB board is placed in a groove of the body 41 and fixed by the cover board 42, the test bottom board 43 is arranged at a lower part of the body 41 and provided with probes 44. The probes 44 pass through the body 41, maintaining a relative position between the test bottom board and the body, to electrically connect with test contacts respectively, thus completing data communication and power supply transmission.

Specifically, a bottom of the body 41 is provided with a plurality of parallel and spaced stiffeners for uniformly supporting the PCB board to be tested, which can avoid damage to the PCB. The cover board 42 is provided with a plurality of parallel and spaced strip-shaped openings, each opening leaks at least one row of optical transceivers, and the cover board 42 can make a surface of the PCB to be tested basically flush.

The test bottom board controls the optical transceivers of each of the plurality of PCB units to emits light in sequence.

When each of the optical transceivers of each of the plurality of PCB units emit light, a light detecting unit is moved to corresponding optical transceiver position to detect a light intensity.

According to light intensity changes of the optical transceivers of each PCB unit before and after the burn-in test, qualified PCB units are selected.

In a specific embodiment, the test system includes a test unit, a detection unit and a module control unit. The test unit informs the module control unit of a serial number and a luminous intensity of a module currently tested, and the module control unit controls each of optical emitters of the corresponding optoelectronic assembly to emits light through the test bottom board according to the received information. The test unit controls the detection unit to move above the corresponding numbered module, that is, above the corresponding optical transceiver, and the detection unit detects the light intensity of the light emitting device of the optoelectronic assembly and transmits the light intensity to the test unit. The test unit processes data obtained by the detection unit and saves a test result.

Therefore, according to the light intensity change of each of the optical transceivers of each PCB unit before and after the burn-in test, qualified PCB units are selected.

Therefore, the test method of the present invention can carry out burn-in tests on the plurality of optoelectronic assemblies in batches, and the test efficiency is high. The optoelectronic assemblies are controlled to emit light through the test tool, and the test method is simple.

The present invention further discloses an optoelectronic assembly prepared by using the above method.

Further, the present invention further discloses a photoelectric unit. The photoelectric unit includes the above optoelectronic assembly, and semi-circular through holes that are located on the side edge of the optoelectronic assembly, are connected with a bottom board.

Refer to FIGS. 4 to 6, which show different schematic diagrams of the optical assembly of the photoelectric unit prepared according to the present invention. In the photoelectric unit, an optical assembly 3 is further included. The optical transceiver 32 is coupled with an optical fiber through the optical assembly 3.

In conclusion, the present invention has the following advantages.

1. According to the packaging structure of the optoelectronic assembly, the optical transceiver is directly mounted on the base, a pedestal is not needed, only the optical transceiver and the printed circuit board are provided, so the assembly process is simple.

2. The back of the PCB unit is provided with the plurality of electrical contacts, which are used for connecting signals, power supply and ground, and can be connected with the bottom board through SMT welding, and are suitable for reflow soldering surface mount technology.

3. The accommodating space is formed by the protective cover and the PCB unit. The protective cover is made of metal or ceramic, and the optical assembly is made by an integral molding process, with no gap on the surface thereof. The protective cover and the PCB unit are scaled by high-temperature resistant glue, so that the whole module is integrated, which can prevent injection molding materials from entering the cavity and avoid the damage of the optical transceiver and the driver during injection molding.

4. The accommodating space is formed by the protective cover and the PCB unit, and the optical path coupling between the optical transceiver and the optical fiber is realized by different ways such as the optical assembly or the optical fiber guide hole, so that the structure is flexible and simple.

5. Small optoelectronic assemblies can be formed, and the burn-in test of the light emitting device can be realized in a connecting plate stage. Undesirable devices can be found earlier, so the cost is saved. At the same time, the efficiency of the burn-in test is improved. A burn-in test interface can be realized by means of gold finger, board to board connector or probes.

6. A large carrier is provided with the plurality of PCB units, and the plurality of PCB units are cut after the preparation process is completed, so as to prepare the corresponding optoelectronic assembly and improve the assembly efficiency.

7. The burn-in test is carried out before cutting, so that the burn-in test of a plurality of optoelectronic assemblies can be completed at one time, which reduces requirements for a testing tool, and can test a plurality of optoelectronic assemblies in batches with high testing efficiency; and the optoelectronic assemblies are controlled to emit light through the testing tool, and the test method is simple.

The above is a further detailed description of the present invention in combination with specific preferred embodiments, and it cannot be considered that the specific embodiments of the present invention are limited to this. Those of ordinary skills in the art to which the present invention belongs, can make several simple deductions or substitutions without departing from the concept of the present invention, which should all be regarded as belonging to the scope of protection of the present invention determined by the submitted claims.

What is claimed is:

1. A preparation method of an optoelectronic assembly, comprising:
carrier preparation step S110, including acquiring a prepared PCB board, wherein the PCB board is provided with an electrical connection surface and an optical coupling surface at an interval, the PCB board is provided with a plurality of PCB units, and each PCB unit corresponds to an optoelectronic assembly to be prepared;
electrical connection surface preparation step S120, including printing and preparing metal pads on the electrical connection surface, wherein each of the metal pads comprises a plurality of first contacts at a central position and a plurality of second contacts at a periphery of the first contacts, and a surface area of the first contact is larger than a surface area of the second contact; and fixing solder on the first contacts and the second contacts;
chip attaching step S130, including attaching a plurality of driver chips and a plurality of optical transceivers on the optical coupling surface; and
bonding step S140, including electrically connecting electrical contacts of the plurality of driver chips and the plurality of optical transceivers with electrical contacts of the PCB board with each other.

2. The preparation method of the optoelectronic assembly according to claim 1, further comprising:
optical assembly mounting step S150, including aligning and fixing the optical assemblies with the optical transceivers; and
PCB unit preparation step S160, including cutting the PCB board into a plurality of PCB units by using precision cutting, wherein a side edge of the PCB unit is provided with a plurality of semi-circular through holes.

3. The preparation method of the optoelectronic assembly according to claim 1, wherein, in the electrical connection surface preparation step S120, the electrical connection surface is prepared by using a printing plate, the printing plate is provided with a plurality of first through holes and a plurality of second through holes, wherein the first through holes correspond to the first contacts and the second through holes correspond to the second contacts, and the electrical connection surface is prepared by applying solder paste.

4. The preparation method of the optoelectronic assembly according to claim 3, wherein the first through hole is aligned with a center of the first contact, the second through hole is aligned with a center of the second contact, and a first size of the first through hole of the printing plate is 40%-60% of a second size of the first contact; and a third size of the second through hole is 40%-60% of a fourth size of the second contact.

5. The preparation method of the optoelectronic assembly according to claim 3, wherein, in the electrical connection surface preparation step S120, the fixing solder on the first contacts and the second contacts comprises:
distributing and attaching prefabricated solder balls to positions on the printing plate with the solder paste, melting the solder paste and fixing the solder balls by hot-blast heating, and then taking the printing plate away, wherein a temperature of the hot-blast heating is higher than a melting point of the solder paste and lower than a melting point of the solder ball.

6. The preparation method of the optoelectronic assembly according to claim 3, wherein, in the electrical connection surface preparation step S120, the fixing solder on the first contacts and the second contacts comprises taking the printing plate away and heating the solder paste to fix the solder paste on the PCB board.

7. The preparation method of the optoelectronic assembly according to claim 1, wherein, in the chip attaching step S130,
the driver chips are mounted on the optical coupling surface, the optical transceivers are mounted on brackets respectively, and each of the brackets is vertically mounted on the optical coupling surface; or
the driver chips and the optical transceivers are mounted on the optical coupling surface.

8. The preparation method of the optoelectronic assembly according to claim 2, further comprising burn-in test step S145 which is arranged between the bonding step S140 and the optical assembly mounting step S150, wherein the burn-in test step S145 comprises arranging the PCB board on a burn-in carrying tool, setting burn-in conditions, and performing a burn-in test on the optoelectronic assembly.

9. The preparation method of the optoelectronic assembly according to claim 8, wherein:
the burn-in carrying tool comprises a body, a cover board, and a test bottom board; the PCB board is placed in a groove of the body and fixed by the cover board; the test bottom board is arranged at a lower part of the body and provided with probes; and the probes pass through the body, maintaining a relative position between the test bottom board and the body, to electrically connect with test contacts respectively.

10. The preparation method of the optoelectronic assembly according to claim 9, wherein:
the test bottom board controls the optical transceivers of each of the plurality of PCB units to emit light in sequence;
when the optical transceivers of each of the plurality of PCB units emit light, a light detecting unit is moved to a position of corresponding optical transceiver to detect a light intensity; and
according to light intensity changes of the optical transceivers of each PCB unit before and after the burn-in test, qualified PCB units are selected.

11. An optoelectronic assembly, wherein the optoelectronic assembly is prepared by a preparation method, the preparation method comprising:
carrier preparation step S110, comprising acquiring a prepared PCB board, wherein the PCB board is provided with an electrical connection surface and an optical coupling surface at an interval, the PCB board is provided with a plurality of PCB units, and each PCB unit corresponds to the optoelectronic assembly to be prepared;
electrical connection surface preparation step S120, comprising printing and preparing metal pads on the electrical connection surface, wherein the metal pads comprise a plurality of first contacts at a central position and a plurality of second contacts at a periphery of the first contacts, and a surface area of the first contact is larger than a surface area of the second contact; and fixing solder on the first contacts and the second contacts;
chip attaching step S130, comprising attaching a plurality of driver chips and a plurality of optical transceivers on the optical coupling surface; and
bonding step S140, comprising electrically connecting electrical contacts of the plurality of driver chips and the plurality of optical transceivers with electrical contacts of the PCB board;
optical assembly mounting step S150, comprising aligning and fixing the optical assemblies with the optical transceivers; and
PCB unit preparation step S160, comprising cutting the PCB board into a plurality of PCB units by using precision cutting, wherein a side edge of the PCB unit is provided with a plurality of semi-circular through holes.

12. The optoelectronic assembly according to claim 11, wherein the semi-circular through holes that are located on the side edge of the optoelectronic assembly, are connected with a bottom board.

13. The optoelectronic assembly according to claim 11, wherein the driver chip and the optical transceiver are mounted on the optical coupling surface, and the optical transceiver is coupled with an optical fiber through the optical assembly.

14. The optoelectronic assembly according to claim 13, further comprising a first lens, a second lens and a reflection plane, wherein the optical assembly comprises one accommodating cavity, the first lens is aligned with an emission window of the optical transceiver, and the second lens is aligned with an end face of the optical fiber.

15. The optoelectronic assembly according to claim 14, further comprising a first protective cover, wherein the first protective cover is provided on the outside of the first lens, the second lens and the reflection plane.

16. The optoelectronic assembly according to claim 13, wherein:
the optical transceiver is mounted on the optical coupling surface through a bracket,
the optical assembly is an optical fiber guide hole; and
a side frame is further provided on the optical coupling surface, and an optical fiber guide hole is mounted on the side frame, and the optical fiber guide hole is aligned with a center of the emission window of the optical transceiver.

17. The optoelectronic assembly according to claim 15, further comprising:
a second protective cover, wherein the second protective cover is provided on the outside of the driver chips and the bracket.
